(19) United States
(12) Patent Application Publication
(10) Pub. No.: US 2014/0028162 A1
(43) Pub. Date: Jan. 30, 2014

(54) CASE FOR PORTABLE ELECTRONIC DEVICE

(71) Applicant: Michelle Lynn Carlson, Newbury Park, CA (US)

(72) Inventor: Michelle Lynn Carlson, Newbury Park, CA (US)

(21) Appl. No.: 13/625,776

(22) Filed: Sep. 24, 2012

Related U.S. Application Data
(60) Provisional application No. 61/676,034, filed on Jul. 26, 2012.

(51) Int. Cl. H05K 5/02; B32B 38/10

(52) U.S. Cl. 312/223.1; 156/256; 156/250

(57) ABSTRACT

A method for fabricating a case for a portable electronic device and cases for portable electronics devices are disclosed. A piece of decorative sheet material may be cut from a larger sheet of the decorative sheet material. The piece of decorative sheet material cut to essentially the same size as an inner surface of a transparent back plate, the transparent back plate and a rim collectively forming a housing for the portable electronic device. The piece of decorative sheet material may be bonded to the inner surface of the transparent back plate.

### NOTICE OF COPYRIGHTS AND TRADE DRESS

A portion of the disclosure of this patent document contains material which is subject to copyright protection. This patent document may show and/or describe matter which is or may become trade dress of the owner. The copyright and trade dress owner has no objection to the facsimile reproduction by anyone of the patent disclosure as it appears in the Patent and Trademark Office patent files or records, but otherwise reserves all copyright and trade dress rights whatsoever.

### BACKGROUND

### Field

This disclosure relates to cases for cellular telephones and other portable electronic devices.

### DESCRIPTION OF THE DRAWINGS

FIG. 1 is a photograph showing a perspective back view of a case for a portable electronic device.

FIG. 2 is a photograph showing a perspective front view of the case.

FIG. 3 is an exploded view of the primary components of the case.

FIG. 4 is a flow chart of a process for fabricating the case.

FIG. 5 shows flow charts for other processes for fabricating the case.

### DETAILED DESCRIPTION

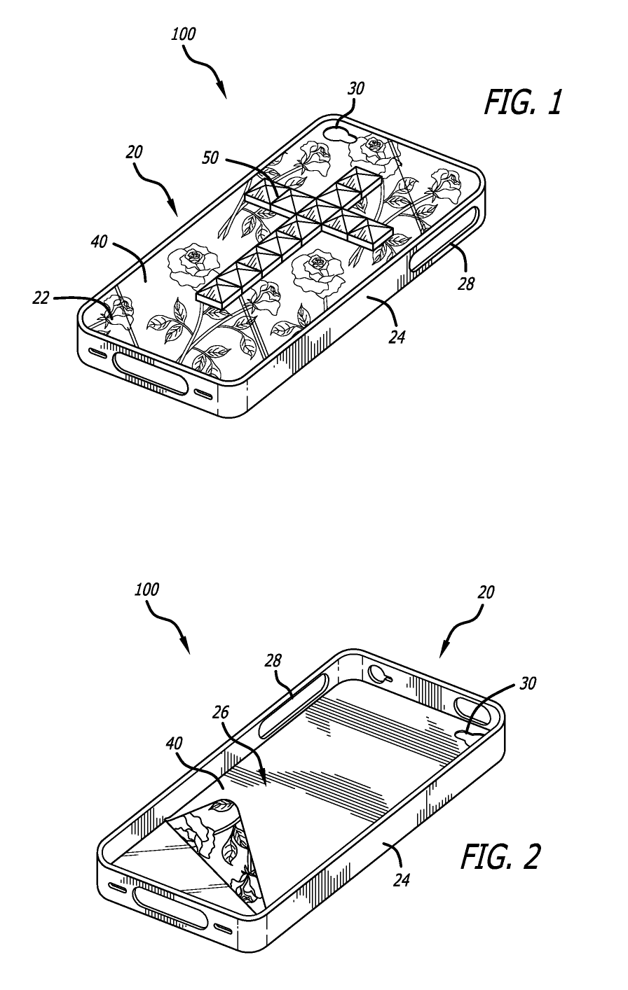

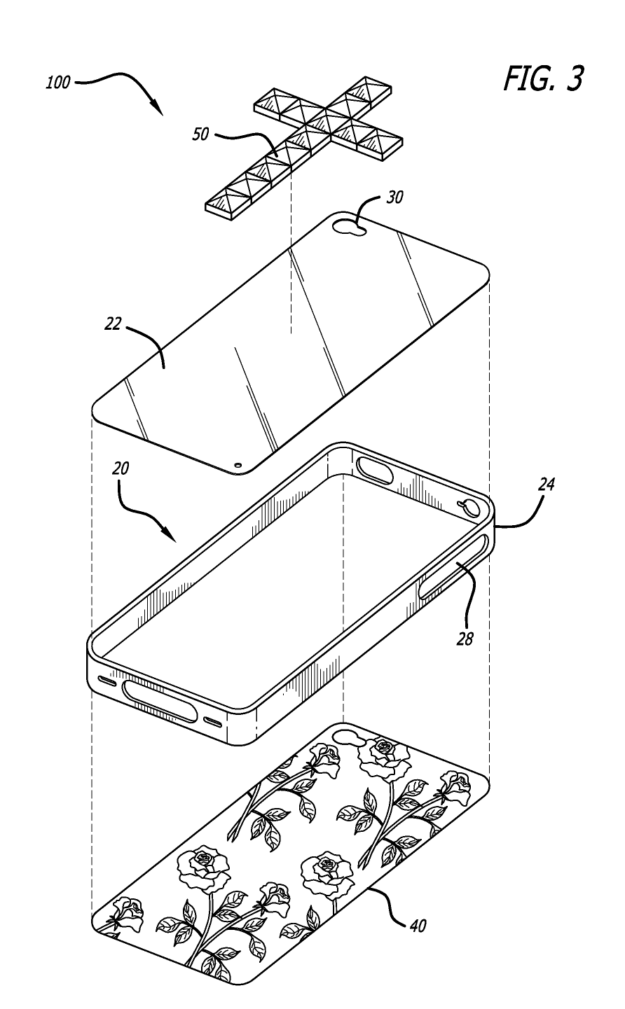

FIG. 1 shows a perspective view of the back of a case 100 for a portable electronic device. FIG. 2 shows a perspective front view of the case 100. FIG. 3 is an exploded perspective view of the back of the case showing the components of the case 100. Generally the same elements can be seen in all three figures.

The case 100 includes a housing 20 including a transparent back plate 22 affixed to a rim 24. The back plate 22 and the rim 24 form a shallow cavity 26 to house the portable electronic device. The portable electronic device (not shown) may be a thin rectangular slab having a front face, a back face, and four edges. The portable electronic device may fit into the cavity 26 with its back face against the back plate 22 of the case 100 and its front face substantially exposed. One or more openings 28 may be provided in the rim 24 to allow access to controls and/or connectors located on the edges of the portable electronic device. One or more opening 30 may be provided in the back plate 22 to provide an aperture for a camera of the portable electronic device.

A decorative sheet material 40 may be attached to an inner surface of the back plate 22 such the decorative sheet material is visible to a user through the transparent back plate 22. Or more decorative elements, such as square metallic studs, may be bonded to an outer surface of the back plate 22. The term “metallic” refers to a visual appearance of the studs and the studs are not necessarily formed of a metal. In the example of FIG. 1, twelve studs are arranged to form a cross 50. Other types and shapes of decorative elements may be used. More or fewer than twelve decorative elements and other arrangements of decorative elements may be used. For example, the cross 50 may be formed as a single piece. Decorative elements may cover only a portion of the outer surface of the back plate 22 such that the decorative sheet material 40 is visible through at least a portion of the back plate 22.

The back plate 22 may be a transparent rigid or flexible plastic material such as an acrylic or polycarbonate plastic. The rim 24 may be a transparent or opaque plastic material. The rim 24 may be elastic, such that the rim 24 can be stretched slightly to allow the portable electronic device to be inserted into the cavity 26. The rim 24, when not stretched, may be configured to retain the portable electronic device within the cavity. The rim 24 may be resilient to provide at least some protection to the portable electronic device, for example in the situation where the portable electronic device is dropped. The back plate 22 and the rim 24 may be attached to each other by, for example, adhesive bonding, thermal bonding, or some other technique.

The decorative sheet material 40 may be woven or knit fabric having an attractive pattern, such as the floral pattern visible in FIG. 1 and FIG. 2. The decorative sheet material 40 may be cut to fit the inner surface of the back plate 22. The decorative sheet material 40 may be cut from a long roll or bolt of fabric. A large number of non-identical pieces of decorative sheet material may be cut from a roll of fabric such that a corresponding large number of unique cases may be assembled. The number of non-identical pieces of decorative sheet material that may be cut from a roll of fabric may depend on a pattern repeat interval of the fabric. For example, 30 or 50 or more different pieces of decorative sheet material may be cut from a roll of fabric. The decorative sheet material may be a material other than a woven or knit fabric. For example, the decorative sheet material may be a printed plastic or paper sheet such as wallpaper.

A case may be designed to accommodate a specific type or model of portable electronic device. For example, the case 100 is designed to accommodate an IPHONE 4S manufacturer by APPLE. Similar cases may be designed to hold other portable electronic devices including, for example, cellular telephones from other manufacturers and portable media players.

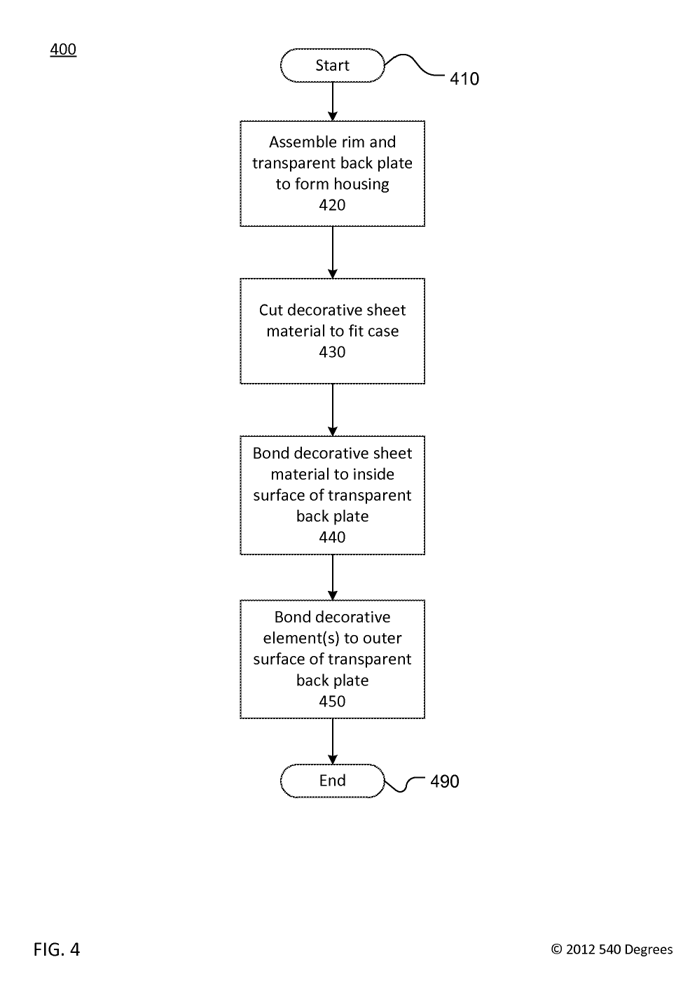

Referring now to FIG. 4, a process 400 for constructing a case of a portable electronic device may begin at 410 and end at 490.

At 420, a rim and a transparent back plate may be assembled to form a housing such as the housing 20. The transparent back plate and the rim may be assembled by, for example, adhesive bonding, thermal bonding, or some other technique.

At 430, a piece of decorative material sized to fit within the housing may be cut from a large sheet or bolt of the decorative material. The decorative sheet material may be cut to essentially the same size as an inner surface of the transparent back plate. In this context, the decorative sheet material is “essentially” the same size as the inner surface of the transparent back plate if the decorative sheet material appears to cover the transparent back plate when a completed case is viewed from the back. The decorative sheet material may be slightly larger than, smaller than, or irregular compared to the transparent back plate as long as the differences are not visible to after a case is completed.

Optionally, at 430, one or more openings may be cut in the piece of decorative material. For example, an opening may be cut in the piece of decorative material to provide an aperture for a camera included in the portable electronic device to be housed within the case.

The decorative material may be cut, for example, by marking the material using a template and cutting the material by hand using a scissors or blade. The decorative material may be cut using a steel rule die. The decorative material may be cut using a computer-controlled pattern cutter. The decorative material may be cut using a computer-controlled laser cutter. The decorative material may be cut using some other technique.

At 440, the piece of decorative material cut at 430 may be bonded to an inside surface of the transparent back plate of the housing. Bonding the decorative material to the inside surface may include application an adhesive to the inside surface and/or the decorative material, positioning the decorative material on the inside surface, and curing the adhesive. The adhesive may be a liquid applied, for example, by brushing or spraying onto the inside surface and/or the decorative material. The adhesive may be a dry film pre-cut in the same shape as the piece of decorative material. Other types of adhesive may be used. The adhesive may be cured by the passage of time, by heat, by ultraviolet light transmitted through the transparent back plate and/or the decorative material, or by some other method.

At 450 one or more optional decorative elements, such as the cross 50, may be bonded to an outer surface of the back plate. The decorative elements may be bonded to the back plate using, for example, a liquid adhesive or a dry film adhesive first applied to the decorative elements. The decorative elements may be positioned on the outside surface manually using a template or other positioning guide. The decorative elements may be positioned on the case using a computer controlled pick-and-place machine, or by some other method. Where necessary, the adhesive used to bond the decorative elements may be cured by the passage of time, by heat, by ultraviolet light, or by some other method.

The process 400 may end at 490 after the decorative material and optional decorative elements have been bonded to the back plate and all adhesives have been cured.

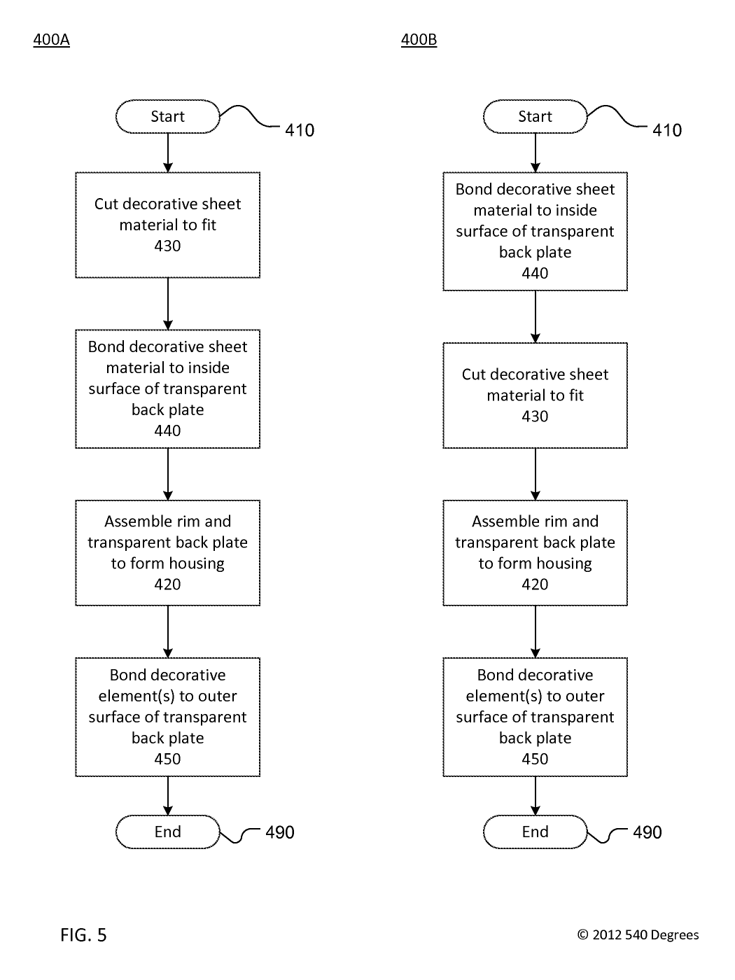

The actions of the process 400 may be performed in a different order. For example, FIG. 5 shows flow charts of alternative processes 400A and 400B. The actions within the process 400A and the process 400B are generally similar to the counterpart actions in the process 400 of FIG. 4. In the process 400A, the assembly of the rim and transparent back plate to form the housing at 420 occurs after the decorative sheet material is bonded to the transparent back plate at 440. Since the transparent back plate is planar at the time of the bonding at 440, the bonding step may be simplified. For example, a roller may be used to apply adhesive to the transparent back plate and/or to press the decorative sheet material to the planar transparent back plate.

In the process 400B, the decorative sheet material may be bonded to the transparent back plate at 440 before the decorative sheet material is cut to size at 430. For example, an oversized piece of decorative sheet material may be bonded to a transparent back plate at 440. The decorative sheet material may then be cut to size at 430 using the transparent back plate as a template for cutting, thus ensuring perfect alignment between the decorative sheet material and the back plate. Bonding the decorative sheet material to the transparent back plate before cutting may also inhibit fraying of the decorative sheet material.

Other variations of the process 400 may be used. For further example, decorative elements may be bonded to the outer surface of the transparent back plate at 450 before the decorative sheet material is bonded at 440 and/or before the transparent back plate and the rim are assembled at 420.

It is claimed:

1. A method for fabricating a case for a portable electronic device, comprising:
cutting a piece of decorative sheet material from a larger sheet of the decorative sheet material, the piece of decorative sheet material cut to essentially the same size as an inner surface of a transparent back plate, the transparent back plate and a rim collectively forming a housing having a cavity to house the portable electronic device; and
bonding the piece of decorative sheet material to the inner surface of the transparent back plate.

2. The method of claim 1, wherein the bonding is performed after the transparent back plate is assembled to the rim to form the housing.

3. The method of claim 1, wherein the bonding is performed before the transparent back plate is assembled to the rim to form the housing.

4. The method of claim 3, wherein the cutting is performed after the bonding.

5. The method of claim 1 wherein the decorative sheet material is a fabric.

6. The method of claim 1, wherein cutting a piece of decorative sheet material from a larger sheet of the decorative sheet material includes cutting one or more opening in the piece of decorative material.

7. The method of claim 1, further comprising:
bonding one or more decorative elements to an outer surface of the transparent back plate.

8. A case for a portable electronic device fabricated by a method comprising:
cutting a piece of decorative sheet material from a larger sheet of the decorative sheet material, the piece of decorative sheet material cut to essentially the same size as an inner surface of a transparent back plate, the transparent back plate and a rim collectively forming a housing having cavity to house the portable electronic device; and
bonding the piece of decorative sheet material to the inner surface of the transparent back plate.

9. The case of claim 8, wherein the bonding is performed after the transparent back plate is assembled to the rim to form the housing.

10. The case of claim 8, wherein the bonding is performed before the transparent back plate is assembled to the rim to form the housing.

11. The case of claim 10, wherein the cutting is performed after the bonding.

12. The case of claim 8 wherein the decorative sheet material is a fabric.

13. The case of claim 8, wherein cutting a piece of decorative sheet material from a larger sheet of the decorative sheet material includes cutting one or more opening in the piece of decorative material.

14. The method of claim 1, fabricated by a method that further comprises:
bonding one or more decorative elements to an outer surface of the transparent back plate.

15. A case for a portable electronic device, comprising:
a transparent back plate;
a rim assembled to the transparent back plate, the rim and the transparent back plate collectively forming a housing having a cavity to house the portable electronic device;
a piece of decorative sheet material bonded to an inner surface of the transparent back plate.

16. The case of claim 16, further comprising:
one or more decorative elements bonded to an outside surface of the transparent back plate.
